(19) United States
(12) Patent Application Publication
(10) Pub. No.: US 2025/0266351 A1
(43) Pub. Date: Aug. 21, 2025

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Youn Seok KIM, Icheon-si Gyeonggi-do (KR); Jae Taek KIM, Icheon-si Gyeonggi-do (KR)

(73) Assignee: SK hynix Inc., Icheon-si Gyeonggi-do (KR)

(21) Appl. No.: 18/663,306

(22) Filed: May 14, 2024

(30) Foreign Application Priority Data
Feb. 19, 2024 (KR) 10-2024-0023821

(51) Int. Cl. H01L 23/528; H01L 23/522; H10B 41/10; H10B 41/27; H10B 41/40; H10B 43/10; H10B 43/27; H10B 43/40

(52) U.S. Cl. CPC H01L 23/5283; H01L 23/5226; H01L 23/528; H10B 41/10; H10B 41/27; H10B 41/40; H10B 43/10; H10B 43/27; H10B 43/40

(57) ABSTRACT

A semiconductor device includes: a peripheral circuit, a stack located over the peripheral circuit, a bonding pad located between the peripheral circuit and the stack, a probing pad located between the peripheral circuit and the stack and connected to the bonding pad, a contact plug extending through the stack and electrically connected to the peripheral circuit through the probing pad and the bonding pad, and a contact structure including a contact connect portion extending in a first direction, a first contact via protruding from the contact connect portion in a second direction intersecting the first direction, and a second contact via spaced apart from the first contact via and protruding from the contact connection portion in the second direction.

### CROSS-REFERENCE TO RELATED APPLICATION

This application claims priority under 35 U.S.C. § 119 (a) to Korean Patent Application No. 10-2024-0023821 filed in the Korean Intellectual Property Office on Feb. 19, 2024, which application is incorporated herein by reference in its entirety.

### BACKGROUND

### 1. Technical Field

Embodiments of the present disclosure generally relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a peripheral circuit; a stack located over the peripheral circuit; a bonding pad located between the peripheral circuit and the stack; a probing pad located between the peripheral circuit and the stack and connected to the bonding pad; a contact plug extending through the stack and electrically connected to the peripheral circuit through the probing pad and the bonding pad; and a contact structure including a contact connect portion extending in a first direction, a first contact via protruding from the contact connect portion in a second direction intersecting the first direction, and a second contact via spaced apart from the first contact via and protruding from the contact connection portion in the second direction.

In an embodiment, a semiconductor device may include: a stack; a contact structure including contact vias at least partially extending through the stack and spaced apart from each other in a first direction and a contact connection portion extending in the first direction to connect the contact vias to each other and having a U shape in a cross section; and at least one contact plug extending through the stack.

In an embodiment, a manufacturing method of a semiconductor device may include: forming a first stack; forming a trench in the first stack; forming first contact holes extending through the first stack; forming a second stack on the first stack; forming second contact holes extending through the second stack and respectively connected to the first contact holes; forming via holes extending through the second stack and connected to the trench; expanding the via holes and the trench; and forming a contact structure in the expanded via holes and the expanded trench.

### BRIEF DESCRIPTION OF THE DRAWINGS

FIG. 1 is a diagram for describing a semiconductor device in accordance with an embodiment.

FIG. 2 is a diagram for describing a semiconductor device in accordance with an embodiment.

FIGS. 3A, 3B, and 3C are diagrams for describing a semiconductor device in accordance with an embodiment.

FIGS. 4, 5A, 5B, 5C, 5D, 5E, 5F, and 6 are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

According to an embodiment of the present technology, it is possible to provide a semiconductor device having a stable structure and improved reliability.

Hereafter, embodiments in accordance with the technical spirit of the present disclosure will be described with reference to the accompanying drawings. It will be understood that, although the terms “first,” “second,” etc. may be used herein to describe various elements, these elements should not be limited by these terms. These terms are only used to distinguish one element from another element, and the order or number of components is not limited by the terms. The cross-hatching throughout the figures illustrates corresponding or similar areas between the figures rather than indicating the materials for the areas. It will be understood that when an element or layer etc., is referred to as being “on,” “over,” or “connected to,” another element or layer etc., it can be directly on, over, or connected to the other element or layer etc., or intervening elements or layers etc., may be present. In contrast, when an element or layer etc., is referred to as being “directly on,” “directly over,” or “directly connected to” another element or layer etc., there are no intervening elements or layers etc., present. Like numerals refer to like elements throughout. As used herein, the term “and/or” includes any and all combinations of one or more of the associated listed items. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

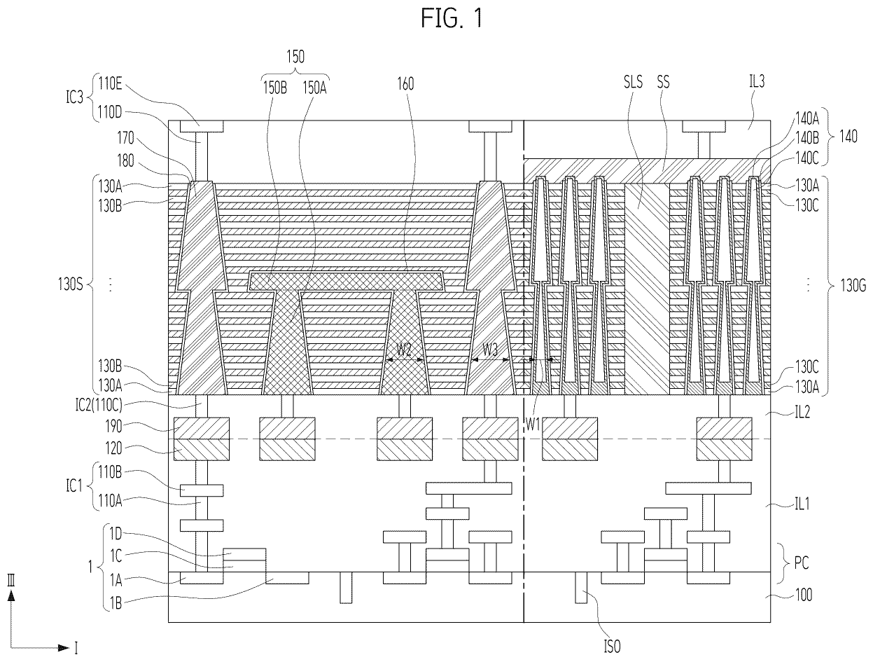

FIG. 1 is a diagram for describing a semiconductor device in accordance with an embodiment.

Referring to FIG. 1, the semiconductor device may include at least one of a substrate 100, a bonding pad 120, a stack 130S, a gate structure 130G, channel structures 140, a contact structure 150, an insulating liner 160, a contact plug 170, an insulating spacer 180, and a probing pad 190. The semiconductor device may further include at least one of a first interconnection structure IC1, a second interconnection structure IC2, a third interconnection structure IC3, a first interlayer insulating layer IL1, a second interlayer insulating layer IL2, a third interlayer insulating layer IL3, a slit structure SLS, an element isolation layer ISO, and a source structure SS.

A peripheral circuit PC may be located on the substrate 100. The peripheral circuit PC may include a transistor 1. The transistor 1 may include junctions 1A and 1B, a gate electrode 1D, and a gate insulating layer 1C. Here, the gate insulating layer 1C may be located between the gate electrode 1D and the substrate 100. The element isolation layer ISO may be located in the substrate 100, and an active region of the transistor 1 may be defined by the element isolation layer ISO.

The first interconnection structure IC1 may be located on the peripheral circuit PC. The first interconnection structure IC1 may be located in the first interlayer insulating layer IL1. Here, the first interlayer insulating layer IL1 may be located on the substrate 100. The first interconnection structure IC1 may include first vias 110A and first wiring lines 110B. At least one of the first vias 110A may be connected to the transistor 1, and may connect the first wiring lines 110B to each other. The first interconnection structure IC1 may include a conductive material such as tungsten. The first interlayer insulating layer IL1 may include an insulating material such as oxide or nitride.

The bonding pad 120 may be located between the peripheral circuit PC and the stack 130S. The bonding pad 120 may be located between the peripheral circuit PC and the gate structure 130G. The bonding pad 120 may be located in the first interlayer insulating layer IL1. The bonding pad 120 may include a conductive material such as copper.

The probing pad 190 may be located between the peripheral circuit PC and the stack 130S. For example, the probing pad 190 may be located on the bonding pad 120. The probing pad 190 may be located in the second interlayer insulating layer IL2. Here, the second interlayer insulating layer IL2 may be located on the first interlayer insulating layer IL1. The probing pad 190 may be used to apply a voltage in order to derive an electrical parameter of the contact structure 150 in a manufacturing process of the semiconductor device. The probing pad 190 may be connected to the bonding pad 120. In other words, the probing pad 190 may be used as a bonding pad.

The probing pad 190 may include substantially the same material as or a different material from the bonding pad 120. As an example, the probing pad 190 may include copper. In such a case, an interface between the probing pad 190 and the bonding pad 120 might not exist. As another example, the probing pad 190 may include aluminum. In such a case, an interface between the probing pad 190 and the bonding pad 120 may exist. However, the probing pad 190 is not limited thereto, and may include a conductive material such as copper, tungsten, or aluminum.

The second interconnection structure IC2 may be located on the probing pad 190. The second interconnection structure IC2 may be located in the second interlayer insulating layer IL2. The second interconnection structure IC2 may include a second via 110C (i.e., depicted as IC2 (110C) in FIG. 1). The second via 110C may be connected to the probing pad 190. However, the second interconnection structure IC2 is not limited thereto, and may further include a second wiring line. The second interconnection structure IC2 may include a conductive material such as tungsten. The second interlayer insulating layer IL2 may include an insulating material such as oxide or nitride.

The stack 130S may be located on the peripheral circuit PC. the stack 130S may be located over the peripheral circuit PC and extend away from the peripheral circuit PC in a third direction III as shown in FIG. 1. The stack 130S may include insulating layers 130A and sacrificial layers 130B that are alternately stacked. The insulating layers 130A may each include an insulating material such as oxide, and the sacrificial layers 130B may each include a sacrificial material such as nitride.

The contact structure 150 may be located in the stack 130S. The contact structure 150 may include contact vias 150A and a contact connect portion 150B. The contact vias 150A may extend through the stack 130S, and may be spaced apart from each other in a first direction I. The contact connection portion 150B may connect the contact vias 150A to each other in the first direction I. Accordingly, in an embodiment, the contact structure 150 may have a U shape. In an embodiment, as shown in FIG. 1, the contact structure 150 may include a contact connect portion 150B extending in a first direction intersecting the third direction, a first contact via 150A protruding from the contact connect portion 150B in the third direction, and a second contact via 150A spaced apart from the first contact via 150A and protruding from the contact connection portion 150B in the third direction. In an embodiment, the width of a first contact via 150A may increase as it protruded further from the contact connect portion 150B as shown in FIG. 1. The insulating liner 160 may surround the contact structure 150. The contact structure 150 may be used as a test pattern in the manufacturing process of the semiconductor device. For example, the electrical parameter of the contact structure 150 may be derived by applying a voltage to the probing pads 190. An expansion width of contact holes for forming the contact plugs 170 may be determined through the electrical parameter of the contact structure 150. The contact structure 150 may include a conductive material such as tungsten. The insulating liner 160 may include an insulating material such as oxide.

The contact plugs 170 may extend through the stack 130S. The insulating spacer 180 may surround each of the contact plugs 170. The contact plugs 170 may be electrically connected to the peripheral circuit PC. For example, the contact plugs 170 may be electrically connected to the peripheral circuit PC through the probing pad 190 and the bonding pad 120. The contact plugs 170 may each include a conductive material such as tungsten. The insulating spacer 180 may include an insulating material such as oxide.

The gate structure 130G may be located on the peripheral circuit PC. The gate structure 130G may be located at a level corresponding to the stack 130S. The gate structure 130G may include insulating layers 130A and conductive layers 130C that are alternately stacked. Here, the conductive layers 130C may be layers that have replaced the sacrificial layers 130B in the manufacturing process. The conductive layers 130C may each include a conductive material such as tungsten, polysilicon, or molybdenum.

The conductive layers 130C may be gate lines such as source select lines, word lines, or drain select lines. Source select transistors, memory cells, or drain select transistors may be located in regions where the channel structures 140 and the conductive layers 130C intersect each other. As an example, at least one source select transistor, a plurality of memory cells, and at least one drain select transistor that are stacked along the channel structure 140 may constitute one memory string.

The channel structures 140 may extend through the gate structure 130G. The source structure SS may be located on the gate structure 130G. The channel structures 140 may extend into the source structure SS through the gate structure 130G. Each of the channel structures 140 may include at least one of a channel layer 140A, a memory layer 140B surrounding the channel layer 140A, and an insulating core 140C located in the channel layer 140A. The slit structure SLS may extend through the gate structure 130G. The slit structure SLS may include an insulating material, a conductive material, a semiconductor material, or the like.

The channel structures 140 may each have a first width W1. The contact vias 150A of the contact structure 150 may each have a second width W2. Here, the second width W2 may be greater than the first width W1. The contact plug 170 may have a third width W3. Here, the third width W3 may be greater than the first width W1. The second width W2 and the third width W3 may be substantially the same as or different from each other. For example, the second width W2 and the third width W3 may be substantially the same as each other.

For reference, widths of structures may refer to widths of upper surfaces, widths of lower surfaces, or widths of portions between the upper surfaces and the lower surfaces of the structures. In addition, comparing the widths of the structures with each other may mean comparing widths located at substantially the same level with each other.

The third interconnection structure IC3 may be located on the stack 130S or the gate structure 130G. The third interconnection structure IC3 may be located on the source structure SS and be electrically connected to the source structure SS. The third interconnection structure IC3 may be located in the third interlayer insulating layer IL3. Here, the fourth interlayer insulating layer IL3 may be located on the gate structure 130G. Alternatively, the third interlayer insulating layer IL3 may be located on the source structure SS.

The third interconnection structure IC3 may include third vias 110D and third wiring lines 110E. At least one of the third vias 110D may be connected to the contact plug 170, and may be connected to the source structure SS. At least one of the third wiring lines 110E may be connected to the third via 110D. The third interconnection structure IC3 may include a conductive material such as tungsten. The third interlayer insulating layer IL3 may include an insulating material such as oxide or nitride.

According to the structure described above, the semiconductor device may include the contact structure 150 having the U shape, and may include the probing pad 190. In the manufacturing process of the semiconductor device, the electrical parameter of the contact structure 150 may be derived, and the expansion width of the contact holes for forming the contact plugs 170 may be determined. In addition, the probing pad 190 may be used as a bonding pad connected to the bonding pad 120.

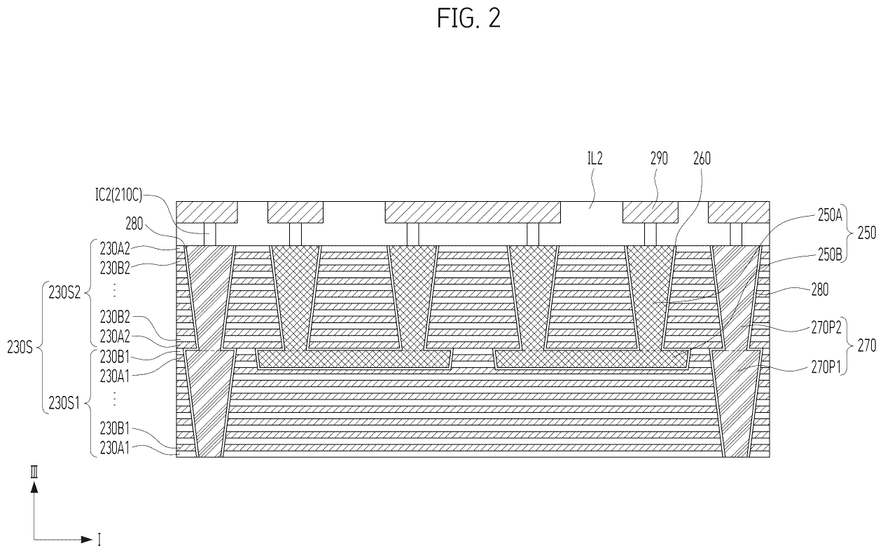

FIG. 2 is a diagram for describing a semiconductor device in accordance with an embodiment. Hereinafter, the content overlapping with the previously described content will be omitted.

Referring to FIG. 2, the semiconductor device may include at least one of a stack 230S, contact structures 250, an insulating liner 260, contact plugs 270, an insulating spacer 280, and probing pads 290. The semiconductor device may further include at least one of a second interlayer insulating layer IL2 and a second interconnection structure IC2.

The stack 230S may include a first stack 230S1 and a second stack 230S2 located on the first stack 230S1. The first stack 230S1 may include first insulating layers 230A1 and first conductive layers 230B1 that are alternately stacked, and the second stack 230S2 may include second insulating layers 230A2 and second conductive layers 230B2 that are alternately stacked. The first insulating layers 230A1 and the second insulating layers 230A2 may each include an insulating material such as oxide, and the first conductive layers 230B1 and the second conductive layers 230B2 may each include a conductive material such as tungsten, molybdenum, or polysilicon.

The contact structures 250 may be spaced apart from each other in the first direction I. The contact structure 250 may include contact vias 250A and a contact connection portion 250B connecting the contact vias 250A to each other. The contact structure 250 may be located in the stack 230S. For example, the contact vias 250A may be located in the second stack 230S2. The contact connection portion 250B may be located between the first stack 230S1 and the second stack 230S2. The insulating liner 260 may surround the contact structure 250. The insulating liner 260 may include an insulating material such as oxide. The contact structure 260 may include a conductive material such as tungsten.

The contact plugs 270 may be spaced apart from each other in the first direction I. The contact structures 250 may be located between the contact plugs 270. The contact plug 270 may be located in the stack 230S. The contact plug 270 may include a first portion 270P1 and a second portion 270P2 located on the first portion 270P1. The first portion 270P1 may be located in the first stack 230S1, and the second portion 270P2 may be located in the second stack 230S2. An upper surface of the first portion 270P1 of the contact plug 270 may be located at substantially the same level as an upper surface of the contact connection portion 250. The insulating spacer 280 may surround each of the contact plugs 270. The insulating spacer 280 may include an insulating material such as oxide. The contact plugs 270 may each include a conductive material such as tungsten.

The probing pads 290 may be located on the contact structures 250. For example, the probing pads 290 may be located on the contact vias 250A. The contact structures 250 may be connected to each other through the probing pad 290 and the second interconnection structure IC2. For example, one end of one contact structure 250 and one end of another contact structure 250 may be connected to the probing pad 290. In other words, the contact structures 250 may be connected to each other in a chain form through the probing pad 290.

In an embodiment, when the contact structures 250 are connected to each other in the chain form, reliable electrical parameters of the contact structures 250 may be derived in a manufacturing process of the semiconductor device. For example, in an embodiment, the reliable electrical parameters may be derived by connecting a plurality of contact structures 250 to each other in one chain form, deriving electrical parameters of the respective contact structures 250, and calculating an average of the derived electrical parameters. For reference, it has been illustrated in FIG. 2 that two contact structures 250 are connected to each other in the chain form, but it is also possible to connect three or more contact structures 250 to each other in the chain form. The probing pad 290 may include a conductive material such as tungsten, copper, or aluminum.

For reference, FIG. 2, in an embodiment, may be a diagram illustrating that the plurality of contact structures 250 are connected to each other in the chain form in order to derive the electrical parameters of the contact structures 250 in the manufacturing process of the semiconductor device. After the electrical parameters are derived, a wafer including the probing pads 290 and the contact structures 250 and a wafer including a peripheral circuit may be bonded to each other. In such a case, the probing pads 290 may be used as bonding pads.

According to an embodiment of the structure described above, the contact structures 250 may be connected to each other in the chain form through the probing pads 290. In such an embodiment, the reliable electrical parameters of the contact structures 250 may be derived in the manufacturing process of the semiconductor device.

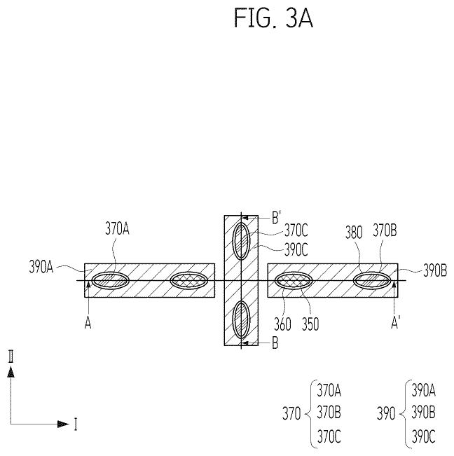

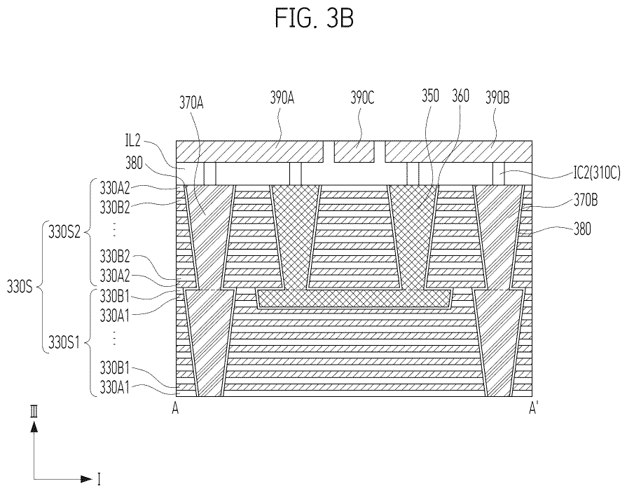

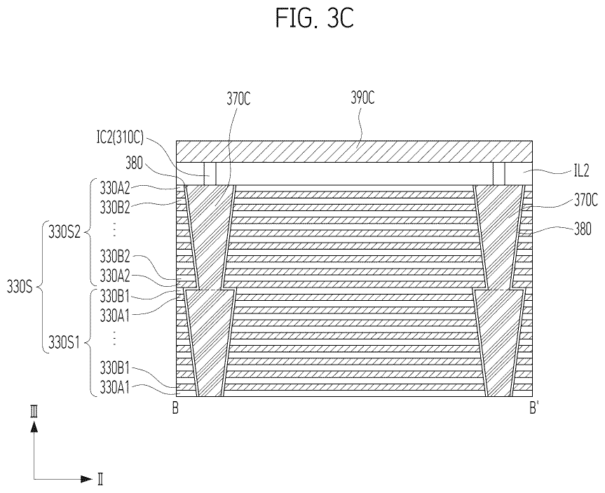

FIGS. 3A to 3C are diagrams for describing a semiconductor device in accordance with an embodiment. FIG. 3A is a plan view, FIG. 3B is a cross-sectional view taken along line A-A′ of FIG. 3A, and FIG. 3C is a cross-sectional view taken along line B-B′ of FIG. 3A.

Referring to FIGS. 3A to 3C, the semiconductor device may include at least one of a stack 330S, a contact structure 350, an insulating liner 360, contact plugs 370, an insulating spacer 380, and contact wiring lines 390. The semiconductor device may further include at least one of a second interlayer insulating layer IL2 and a second interconnection structure IC2. In an embodiment, contact plugs 370 include a first contact plug 370A, a second contact plug 370B, and a third contact plug 370C. In an embodiment, contact wiring lines 390 include a first contact wiring line 390A, a second contact wiring line 390B, and a third contact wiring line 390C.

The stack 330S may include a first stack 330S1 and a second stack 330S2 located on the first stack 330S1. The first stack 330S1 may include first insulating layers 330A1 and first conductive layers 330B1 that are alternately stacked, and the second stack 330S2 may include second insulating layers 330A2 and second conductive layers 330B2 that are alternately stacked. The first insulating layers 330A1 and the second insulating layers 330A2 may each include an insulating material such as oxide, and the first conductive layers 330B1 and the second conductive layers 330B2 may each include a conductive material such as tungsten, molybdenum, or polysilicon.

The contact structure 350 may be located in the stack 330S. The contact structure 350 may have a U shape. The insulating liner 360 may surround the contact structure 350. The insulating liner 360 may include an insulating material such as oxide. The contact structure 350 may include a conductive material such as tungsten.

In an embodiment, the contact plugs 370 may include the first contact plug 370A, the second contact plug 370B, and the third contact plugs 370C. Referring to FIG. 3B, the first contact plug 370A and the second contact plug 370B may be spaced apart from each other in the first direction I. Referring to FIG. 3C, the third contact plugs 370C may be spaced apart from each other in a second direction II intersecting the first direction I. The contact structure 350 may be located between the first contact plug 370A and the second contact plug 370B. The contact plugs 370 may be located in the stack 330S. The insulating spacer 380 may surround each of the contact plugs 370. The insulating spacer 380 may include an insulating material such as oxide. The contact plugs 370 may each include a conductive material such as tungsten.

The contact wiring lines 390 may be located on the contact structure 350. The contact wiring lines 390 may be located on the contact plugs 370. The second interconnection structure IC2 may be located between the contact wiring lines 390 and the contact structure 350 or the contact wiring lines 390 and the contact plugs 370. The contact wiring lines 390 and the contact structure 350 or the contact wiring lines 390 and the contact plugs 370 may be connected to each other through the second interconnection structure IC2.

The contact wiring lines 390 may include a first contact wiring line 390A, a second contact wiring line 390B, and a third contact wiring line 390C. The first contact wiring line 390A and the second contact wiring line 390B may be spaced apart from each other in the first direction I. The third contact wiring line 390C may be located between the first contact wiring line 390A and the second contact wiring line 390B. In such a case, the third contact wiring line 390C exists between the first contact wiring line 390A and the second contact wiring line 390B, and thus, the first contact wiring line 390A and the second contact wiring line 390B might not be connected to each other.

According to an embodiment of the present disclosure, even when the first contact wiring line 390A and the second contact wiring line 390B might not be directly connected to each other, the first contact wiring line 390A and the second contact wiring line 390B may be connected to each other using the contact structure 350 having the U shape. In other words, the first contact wiring line 390A may extend in the first direction I to connect the first contact plug 370A and one end of the contact structure 350 to each other. The second contact wiring line 390B may extend in the first direction I to connect the second contact plug 370B and the other end of the contact structure 350 to each other. The third contact wiring line 390C may extend in the second direction II intersecting the first direction I to connect the third contact plugs 370C to each other.

According to the structure described above, the semiconductor device may have the contact structure 350 having the U shape, and thus, the first contact wiring line 390A and the second contact wiring line 390B may be connected to each other even though the third contact wiring line 390C is located between the first contact wiring line 390A and the second contact wiring line 390B.

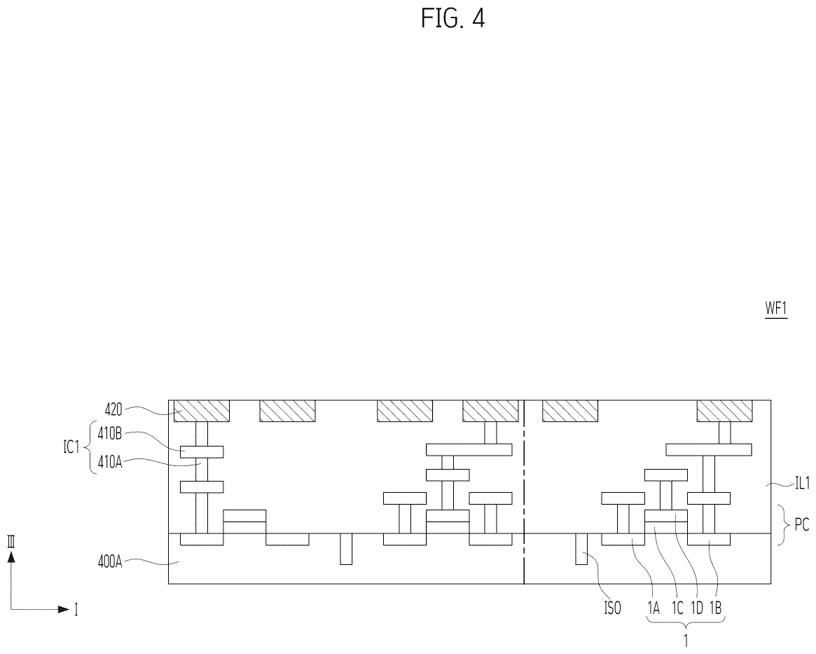

FIGS. 4 to 6 are diagrams for describing a manufacturing method of a semiconductor device in accordance with an embodiment. Hereinafter, the content overlapping with the previously described content will be omitted.

Referring to FIG. 4, a first wafer WF1 including a peripheral circuit PC and a bonding pad 420 may be formed. The peripheral circuit PC may be formed on a first substrate 400A. The peripheral circuit PC may include a transistor 1. An element isolation layer ISO may be formed in the first substrate 400A, and may define an active region of the transistor 1.

A first interconnection structure IC1 may be formed on the first substrate 400A. The first interconnection structure IC1 may be formed in a first interlayer insulating layer IL1. Here, the first interlayer insulating layer IL1 may be formed on the first substrate 400A. The first interconnection structure IC1 may include a first via 410A and a first wiring line 410B. The first via 410A may be connected to the peripheral circuit PC. Alternatively, the first via 410A may connect the first wiring lines 410B to each other. The first interconnection structure IC1 may include a conductive material such as tungsten. The first interlayer insulating layer IL1 may include an insulating material such as oxide.

The bonding pad 420 may be formed on the first interconnection structure IC1. The bonding pad 420 may be formed in the first interlayer insulating layer IL1. The bonding pad 420 may be connected to the peripheral circuit PC through the first interconnection structure IC1. The bonding pad 420 may include a conductive material such as copper.

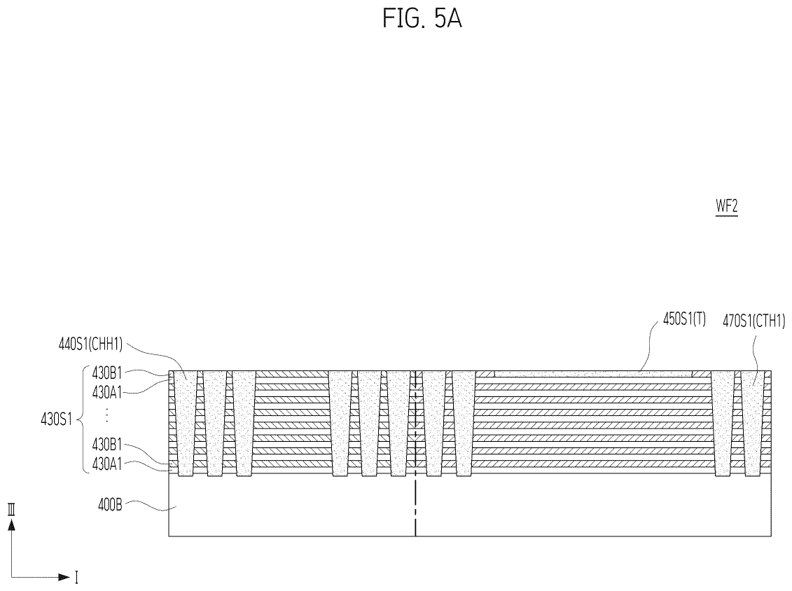

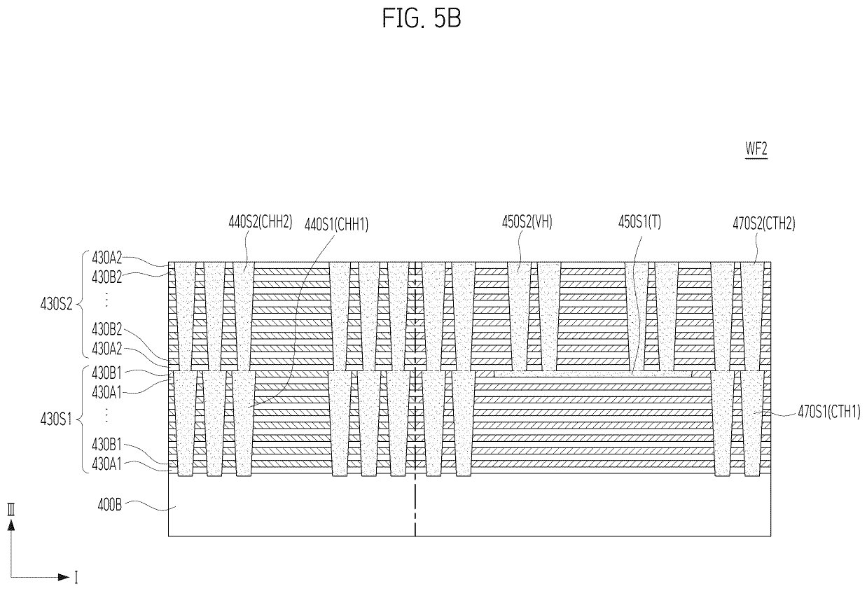

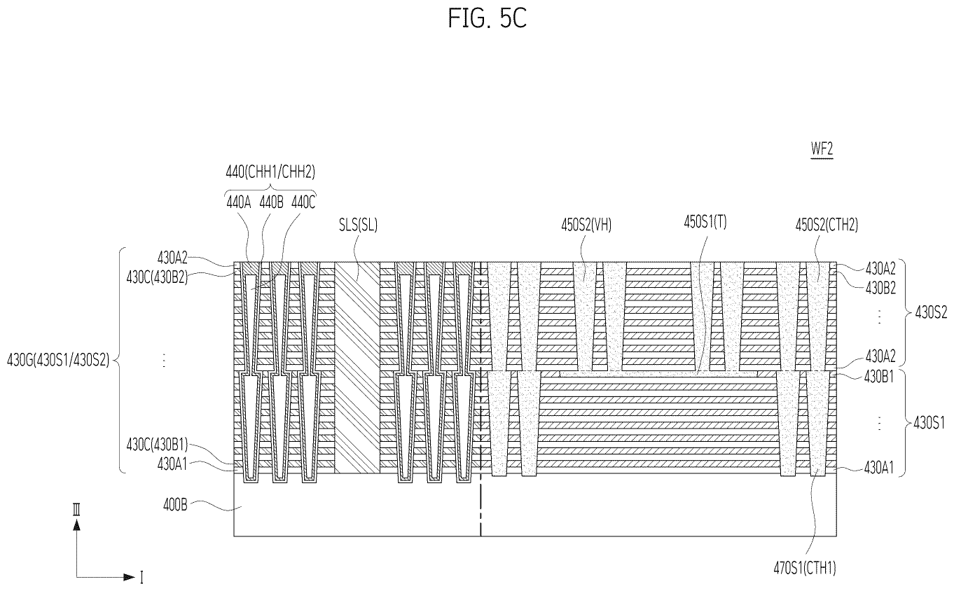

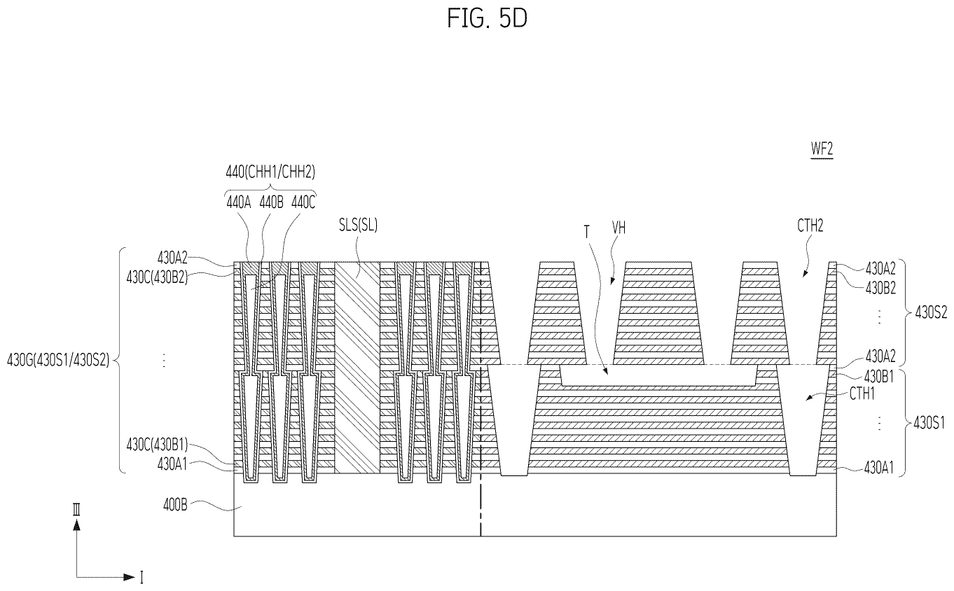

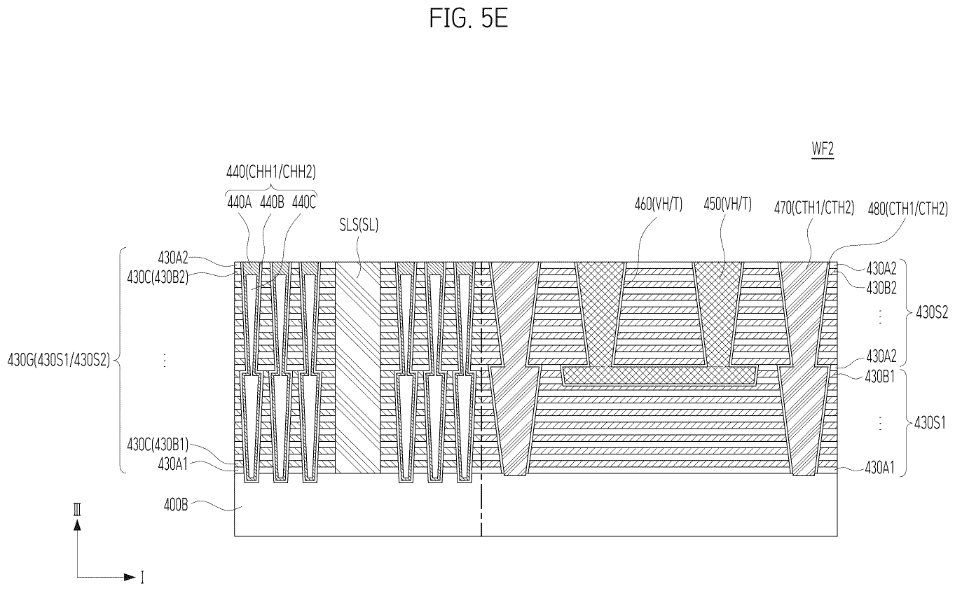

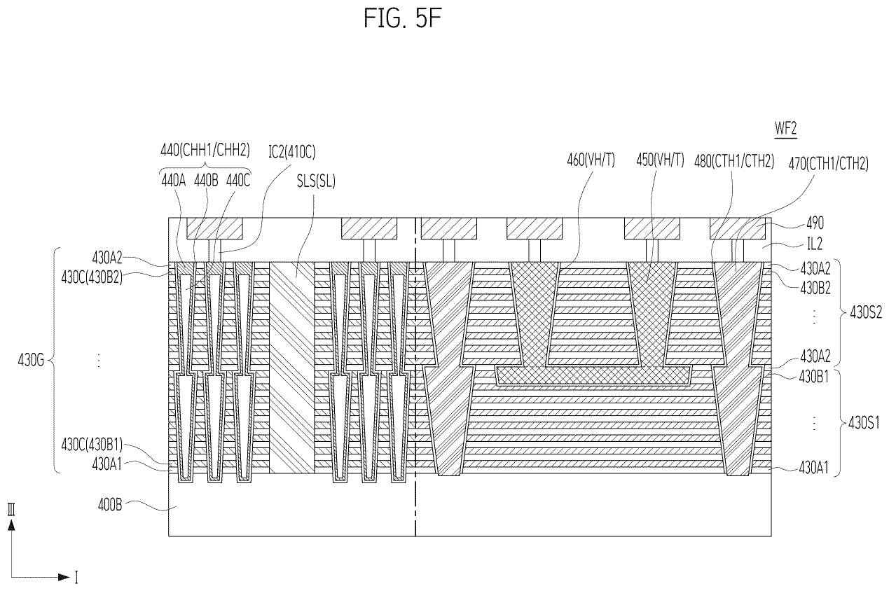

Referring to FIG. 5A, a first stack 430S1 may be formed. For example, the first stack 430S1 may be formed by alternately stacking first material layers 430A1 and second material layers 430B1 on a second substrate 400B. The first material layers 430A1 may each include an insulating material such as oxide, and the second material layers 430B1 may each include a sacrificial material such as nitride.

Subsequently, first channel sacrificial layers 440S1 may be formed in the first stack 430S1. First, first channel holes CHH1 extending into the second substrate 400B through the first stack 430S1 may be formed. Subsequently, the first channel sacrificial layers 440S1 may be formed in the first channel holes CHH1 (i.e., depicted as 440S1 (CHH1) in FIG. 5A). The first channel sacrificial layers 440S1 may each include a sacrificial material such as carbon.

First contact sacrificial layers 470S1 may be formed in the first stack 430S1. First, first contact holes CTH1 extending into the second substrate 400B through the first stack 430S1 may be formed. Here, the first contact holes CTH1 may be formed so that a pair of first contact holes CTH1 are adjacent to each other. When the first contact holes CTH1 are formed, the first channel holes CHH1 may be formed. Subsequently, the first contact sacrificial layers 470S1 may be formed in the first contact holes CTH1 (i.e., depicted as 470S1 (CTH1) in FIG. 5A). The first contact sacrificial layers 470S1 may each include a sacrificial material such as carbon.

A connection portion sacrificial layer 450S1 may be formed in the first stack 430S1. First, a trench T may be formed in the first stack 430S1. For example, the trench T may be formed by etching the uppermost second material layer 430B1 of the first stack 430S1. However, the present disclosure is not limited thereto, and it is also possible to form a relatively deep trench T by etching the second material layers 430B1 and the first material layers 430A1. Subsequently, the connection portion sacrificial layer 450S1 may be formed in the trench T (i.e., depicted as 470S2 (CTH2) in FIG. 5B). The connection portion sacrificial layer 450S1 may include a sacrificial material such as carbon.

Referring to FIG. 5B, a second stack 430S2 may be formed on the first stack 430S1. For example, the second stack 430S2 may be formed by alternately stacking third material layers 430A2 and fourth material layers 430B2 on the first stack 430S1. The third material layers 423A2 may each include an insulating material such as oxide, and the fourth material layers 430B2 may each include a sacrificial material such as nitride.

Subsequently, second channel sacrificial layers 440S2 may be formed in the second stack 430S2. First, second channel holes CHH2 extending through the second stack 430S2 and connected to the first channel holes CHH1, respectively, may be formed. Subsequently, the second channel sacrificial layers 44052 connected to the first channel sacrificial layers 440S1, respectively, may be formed in the second channel holes CHH2 (i.e., depicted as 440S2 (CHH2) in FIG. 5B). The second channel sacrificial layers 440S2 may each include a sacrificial material such as carbon.

Second contact sacrificial layers 470S2 may be formed in the second stack 430S2. First, second contact holes CTH2 extending through the second stack 430S2 and connected to the first contact holes CTH1, respectively, may be formed. Subsequently, the second contact sacrificial layers 470S2 connected to the first contact sacrificial layers 470S1, respectively, may be formed in the second contact holes CTH2 (i.e., depicted as 470S2 (CTH2) in FIG. 5B). The second contact sacrificial layers 470S2 may each include a sacrificial material such as carbon.

Via sacrificial layers 450S2 may be formed in the second stack 430S2. First, via holes VH extending through the second stack 430S2 and connected to the trench T may be formed. Here, the via holes VH may be formed so that a pair of via holes VH are adjacent to each other. When the via holes VH are formed, the second contact holes CTH2 and the second channel holes CHH2 may be formed. Subsequently, the via sacrificial layers 450S2 connected to the connection portion sacrificial layer 450S1 may be formed in the via holes VH (i.e., depicted as 450S2 (VH) in FIG. 5B). The via sacrificial layers 450S2 may each include a sacrificial material such as carbon.

Referring to FIG. 5C, channel structures 440 may be formed. First, the first channel holes CHH1 and the second channel holes CHH2 may be reopened by removing the second channel sacrificial layers 440S2 and the first channel sacrificial layers 440S1. Subsequently, the channel structures 440 may be formed in the first channel holes CHH1 and the second channel holes CHH2 (i.e., depicted as 440 (CHH1/CHH2) in FIG. 5C). Each of the channel structures 440 may include a channel layer 440A, a memory layer 440B surrounding the channel layer 440A, and an insulating core 440C located in the channel layer 440A.

A slit SL extending through the second stack 430S2 and the first stack 430S1 may be formed. The second material layers 430B1 of the first stack 430S1 and the fourth material layers 430B2 of the second stack 430S2 may be replaced with fifth material layers 430C through the slit SL (i.e., depicted as 430C (430B2) and 430 (430B1) in FIG. 5C). The fifth material layers 430C may each include a conductive material such as tungsten, molybdenum, or polysilicon. Consequently, a gate structure 430G including the first material layers 430A1 and the fifth material layers 430C that are alternately stacked and the third material layers 430A2 and the fifth material layers 430C that are alternately stacked may be defined. However, when the second material layers 430B1 and the fourth material layers 430B2 each include a conductive material, a process of replacing the second material layers 430B1 and the fourth material layers 430B2 with the fifth material layers 430C may be omitted. In such a case, the first stack 430S1 and the second stack 430S2 may be used as the gate structure 430G (i.e., depicted as 430G (430S1/430S2) in FIG. 5C). Subsequently, a slit structure SLS may be formed in the slit SL (i.e., depicted as SLS (SL) in FIG. 5C). The slit structure SLS may include at least one of an insulating material, a conductive material, and a semiconductor material.

Referring to FIG. 5D, the via holes VH and the trench T may be expanded. First, the via sacrificial layers 450S2 and the connection portion sacrificial layer 450S1 formed in the via holes VH and the trench T, respectively, may be removed. Subsequently, the via holes VH and the trench T may be expanded by etching the second stack 430S2 and the first stack 430S1. For example, after the via holes VH and the trench T are expanded by etching the first material layers 430A1 and the third material layers 430A2, the via holes VH and the trench T may be expanded by etching the second material layers 430B1 and the fourth material layers 430B2. In such a case, the pair of via holes VH formed adjacent to each other may be expanded to become one expanded via hole VH.

The second contact holes CTH2 and the first contact holes CTH1 may be expanded. For example, when the via holes VH and the trench T are expanded, the second contact holes CTH2 and the first contact holes CTH1 may be expanded. First, the second contact sacrificial layers 470S2 and the first contact sacrificial layers 470S1 formed in the second contact holes CTH2 and the first contact holes CTH1, respectively, may be removed. Subsequently, the second contact holes CTH2 and the first contact holes CTH1 may be expanded by etching the second stack 430S2 and the first stack 430S1. In such a case, a pair of second contact holes CTH2 formed adjacent to each other may be expanded to become one expanded second contact hole CTH2, and the pair of first contact holes CTH1 formed adjacent to each other may be expanded to become one expanded first contact hole CTH1.

Referring to FIG. 5E, a contact structure 450 may be formed in the expanded via holes VH and the expanded trench T. For example, the contact structure 450 may be formed to fill the expanded via holes VH and the expanded trench T. Accordingly, the contact structure 450 may have a U shape. The contact structure 450 may include a conductive material such as tungsten.

Before the contact structure 450 is formed, an insulating liner 460 may be formed in the expanded via holes VH and the expanded trench T. The insulating liner 460 may be conformally formed along profiles of the expanded via holes VH and the expanded trench T. The insulating liner 460 may include an insulating material such as oxide.

A contact plug 470 may be formed in the expanded second contact hole CTH2 and the expanded first contact hole CTH1 (i.e., depicted as 470 (CTH1/CTH2) in FIG. 5E). When the contact structure 450 is formed, the contact plug 470 may be formed. The contact plug 470 may include a conductive material such as tungsten.

Before the contact plug 470 is formed, an insulating spacer 480 may be formed in the expanded second contact hole CTH2 and the expanded first contact hole CTH1 (i.e., depicted as 480 (CTH1/CTH2) in FIG. 5E). First, an insulating liner 460 may be conformally formed in the expanded second contact hole CTH2 and the expanded first contact hole CTH1. Subsequently, the insulating spacer 480 may be formed by etching a bottom surface of the insulating liner 460. The insulating spacer 480 may include an insulating material such as oxide.

Referring to FIG. 5F, probing pads 490 may be formed on the contact structure 450. Consequently, a second wafer WF2 including the contact structure 450 and the probing pads 490 may be formed. Here, the probing pads 490 may be respectively formed on locations of the contact structure 450 corresponding to the expanded via holes VH. The probing pads 490 may be formed in a second interlayer insulating layer IL2 formed on the gate structure 430G or the second stack 430S2. The probing pads 490 and the contact structure 450 may be connected to each other through a second interconnection structure IC2. Here, the second interconnection structure IC2 may include a second via 410C (i.e., depicted as IC2 (410C) in FIG. 5F). The probing pads 490 may each include a conductive material such as copper, tungsten, or aluminum.

Referring again to FIGS. 4 and 5A to 5E, when the first channel holes CHH1 are formed, the first contact holes CTH1 may be formed. When the second channel holes CHH2 are formed, the second contact holes CTH2 and the via holes VH may be formed. Accordingly, the first channel holes CHH1 and the first contact holes CTH1 may be formed to have the same width, and the second channel holes CHH2, the second contact holes CTH2, and the via holes VH may be formed to have the same width.

However, the contact plugs 470 of the second wafer WF2 are used to be connected to the peripheral circuit PC of the first wafer WF1, and it is necessary to expand the first contact holes CTH1 and the second contact holes CTH2. For example, in an embodiment, by expanding the first contact holes CTH1 and the second contact holes CTH2, regions for forming the contact plugs 470 may be secured, and resistance of the contact plugs 470 may be reduced. Accordingly, in an embodiment, it is necessary to determine an expansion width of the first contact holes CTH1 and the second contact holes CTH2.

When the first contact holes CTH1 and the second contact holes CTH2 are expanded, the via holes VH and the trench T may be expanded. In such a case, a width at which the first contact holes CTH1 and the second contact holes CTH2 are expanded may be substantially the same as a width at which the via holes VH are expanded.

According to an embodiment of the present disclosure, an electrical parameter of the contact structure 450 may be derived by applying a voltage to the probing pads 490 connected to the contact structure 450. Here, in an embodiment, the electrical parameter may include an resistive-capacitive (RC) delay value. In an embodiment, the electrical parameter of the contact structure 450 may be compared with a reference value. In such a case, in an embodiment, it may be confirmed whether or not a signal is transmitted at an appropriate speed through the contact structure 450. For example, in an embodiment, when the electrical parameter is greater than the reference value, it may mean that resistance of the contact structure 450 is high. Here, in an embodiment, it may be confirmed that the width of the contact structure 450 should be increased in order to reduce the resistance of the contact structure 450.

In an embodiment, by confirming the electrical parameter of the contact structure 450, electrical parameters of the contact plugs 470 might not be directly derived. In other words, in an embodiment, it may be confirmed whether or not the contact plugs 470 have an appropriate width by confirming the electrical parameter of the contact structure 450 having substantially the same width as the contact plugs 470. Accordingly, in an embodiment, the appropriate width of the contact plugs 470 may be calculated through the electrical parameter derived through the contact structure 450, and thus, the expansion width of the first contact holes CTH1 and the second contact holes CTH2 for forming the contact plugs 470 may be determined.

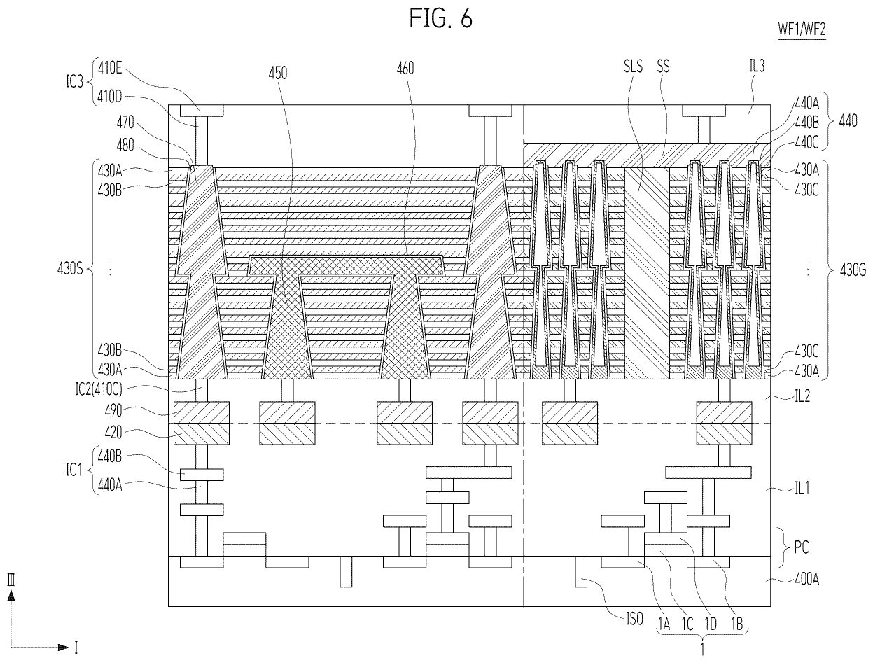

Referring to FIG. 6, the first wafer WF1 and the second wafer WF2 may be bonded to each other as indicated with reference character WF1/WF2. For example, the first wafer WF1 and the second wafer WF2 may be bonded to each other so that the bonding pads 420 of the first wafer WF1 and the probing pads 490 of the second wafer WF2 are connected to each other. Here, in an embodiment, the probing pads 490 may be used as bonding pads. Subsequently, the second substrate 400B may be removed. Subsequently, a source structure SS connected to the channel structures 440 may be formed. Before the source structure SS is formed, the channel layers 440A may be exposed by partially removing the memory layers 440B of the channel structures 440. Subsequently, a third interconnection structure IC3 may be formed on the source structure SS. The third interconnection structure IC3 may be formed on the contact plugs 470. The third interconnection structure IC3 may be located in a third interlayer insulating layer IL3. The third interconnection structure IC3 may include a third via 410D and a third wiring line 410E. The third via 410D may be connected to at least one of the contact plugs 470. The third via 410D may be connected to the source structure SS.

According to an embodiment of the manufacturing method described above, the electrical parameter of the contact structure 450 having the U shape may be derived by applying the voltage to the probing pads 490. In an embodiment, the expansion width of the first contact holes CTH1 and the second contact holes CTH2 may be determined through the electrical parameter of the contact structure 450.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a peripheral circuit;
a stack located over the peripheral circuit;
a bonding pad located between the peripheral circuit and the stack;
a probing pad located between the peripheral circuit and the stack and connected to the bonding pad;
a contact plug extending through the stack and electrically connected to the peripheral circuit through the probing pad and the bonding pad; and
a contact structure including a contact connect portion extending in a first direction, a first contact via protruding from the contact connect portion in a second direction intersecting the first direction, and a second contact via spaced apart from the first contact via and protruding from the contact connection portion in the second direction.

2. The semiconductor device of claim 1, wherein the contact structure comprises substantially a U shape.

3. The semiconductor device of claim 1, further comprising:
a gate structure located over the peripheral circuit; and
channel structures extending through the gate structure.

4. The semiconductor device of claim 3, wherein the channel structures each have a first width in the first direction, and the first contact via and the second contact via each have a second width in the first direction greater than the first width.

5. The semiconductor device of claim 3, wherein the channel structures each have a first width in the first direction, and the contact plug has a third width in the first direction that is greater than the first width.

6. The semiconductor device of claim 1, further comprising an insulating liner surrounding the contact structure.

7. The semiconductor device of claim 1, further comprising an insulating spacer surrounding the contact plug.

8. A semiconductor device comprising:
a stack;
a contact structure including contact vias at least partially extending through the stack and spaced apart from each other in a first direction and a contact connection portion extending in the first direction to connect the contact vias to each other and having a U shape in a cross section; and
at least one contact plug extending through the stack.

9. The semiconductor device of claim 8, wherein the stack includes a first stack and a second stack located on the first stack, and
the contact connection portion is located between the first stack and the second stack, and
the contact vias are located in the second stack.

10. The semiconductor device of claim 9, wherein the contact plugs each include a first portion located in the first stack and a second portion located in the second stack, and
an upper surface of the contact connection portion is located at substantially the same level as an upper surface of the first portion.

11. The semiconductor device of claim 8, further comprising probing pads respectively located on the contact vias.

12. The semiconductor device of claim 8, further comprising an insulating liner surrounding the contact structure.

13. The semiconductor device of claim 8, further comprising an insulating spacer surrounding each of the at least one contact plug.

14. The semiconductor device of claim 8, wherein the at least one contact plug includes a first contact plug and a second contact plug, and
the contact structure is located between the first contact plug and the second contact plug.

15. The semiconductor device of claim 14, further comprising:
a first contact wiring line connecting the first contact plug and one end of the contact structure to each other and extending in the first direction;
a second contact wiring line connecting the second contact plug and the other end of the contact structure to each other and extending in the first direction; and
a third contact wiring line located between the first contact wiring line and the second contact wiring line and extending in a second direction intersecting the first direction.

16. A manufacturing method of a semiconductor device, the manufacturing method comprising:
forming a first stack;
forming a trench in the first stack;
forming first contact holes extending through the first stack;
forming a second stack on the first stack;
forming second contact holes extending through the second stack and respectively connected to the first contact holes;
forming via holes extending through the second stack and connected to the trench;
expanding the via holes and the trench; and
forming a contact structure in the expanded via holes and the expanded trench.

17. The manufacturing method of claim 16, wherein when the via holes are formed, the second contact holes are formed.

18. The manufacturing method of claim 16, further comprising expanding the first contact holes and the second contact holes when the via holes and the trench are expanded.

19. The manufacturing method of claim 18, further comprising forming contact plugs in the expanded first contact holes and the expanded second contact holes.

20. The manufacturing method of claim 19, wherein when the contact structure is formed, the contact plugs are formed.

21. The manufacturing method of claim 19, further comprising, before the forming of the contact structure, forming an insulating liner in the expanded via holes and the expanded trench.

22. The manufacturing method of claim 19, further comprising, before the forming of the contact structure, forming an insulating spacer in the expanded first contact holes and the expanded second contact holes.

23. The manufacturing method of claim 16, further comprising forming probing pads on the contact structure.

24. The manufacturing method of claim 23, wherein the probing pads are respectively formed on locations of the contact structure corresponding to the expanded via holes.

25. The manufacturing method of claim 23, further comprising:
deriving an electrical parameter of the contact structure by applying a voltage to the probing pads;
comparing the electrical parameter of the contact structure with a reference value; and
determining an expansion width of the first contact holes and the second contact holes according to the electrical parameter.

26. The manufacturing method of claim 25, wherein the electrical parameter includes an resistive-capacitive (RC) delay value.

27. The manufacturing method of claim 23, further comprising bonding a first wafer and a second wafer to each other, the first wafer including a peripheral circuit and bonding pads located on the peripheral circuit, and the second wafer including the contact structure and the probing pads.

28. The manufacturing method of claim 27, wherein the first wafer and the second wafer are bonded to each other so that the bonding pads and the probing pads are connected to each other.
